(19) United States
(12) Patent Application Publication
(10) Pub. No.: US 2026/0026406 A1
(43) Pub. Date: Jan. 22, 2026

(54) SEMICONDUCTOR ARRANGEMENT

(71) Applicant: Infineon Technologies Austria AG, Villach (AT)

(72) Inventors: Ralf Otremba, Kaufbeuren (DE); Chwee Pang Tommy Khoo, Bukit Rambai (MY); Chin Yong Tan, Muar (MY); Daniele Miatton, Carbonara al Ticino (IT); Claudio Villani, Zinasco (IT); Zhe Zhang, Heidelberg (DE)

(21) Appl. No.: 19/269,100

(22) Filed: Jul. 15, 2025

(30) Foreign Application Priority Data
Jul. 17, 2024 (DE) 102024206697.4

(51) Int. Cl. H01L 25/16; H01L 23/00; H01L 23/31; H01L 23/495; H10D 80/30

(52) U.S. Cl. CPC H01L 25/162; H01L 23/3114; H01L 23/49537; H01L 23/49562; H01L 23/49575; H01L 24/32; H01L 24/48; H01L 24/73; H10D 80/30; H01L 23/4952; H01L 2224/32245; H01L 2224/48137; H01L 2224/48247; H01L 2224/73265

(57) ABSTRACT

A semiconductor arrangement includes first and second controllable semiconductor devices forming a half-bridge arrangement, each controllable semiconductor device including a control electrode and a controllable load path between a first load electrode and a second load electrode. At least one gate driver is configured to generate one or more control signals for one or more of the controllable semiconductor devices. The first controllable semiconductor device is arranged on and electrically coupled to a first lead frame of a plurality of lead frames. The second controllable semiconductor device is arranged on and electrically coupled to a second lead frame of the plurality of lead frames. The controllable semiconductor devices and the at least one gate driver are arranged in a molded package. Each lead frames is partly covered by the molded package and has at least one surface or section that is not covered by the molded package.

### TECHNICAL FIELD

The instant disclosure relates to a semiconductor arrangement, in particular a semiconductor arrangement comprising semiconductor devices in a half-bridge arrangement.

### BACKGROUND

Power semiconductor module arrangements often include at least one semiconductor substrate arranged in a housing. A semiconductor arrangement including a plurality of controllable semiconductor elements (e.g., two IGBTs in a half-bridge configuration) or non-controllable semiconductor elements (e.g., arrangements of diodes) is arranged on each of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. The second metallization layer may optionally be attached to a base plate. Such conventional power semiconductor module arrangements, however, are large and, therefore, also expensive. For at least some applications, (controllable) semiconductor elements housed in a molded package (e.g., discrete power package) may be used instead for improved cost and performance on system-level.

There is a need for a semiconductor arrangement that is small in size, has an optimized performance, and is capable also for high current ratings.

### SUMMARY

A semiconductor arrangement includes a first controllable semiconductor device, and a second controllable semiconductor device forming a half-bridge arrangement, each of the first and second controllable semiconductor device including a control electrode and a controllable load path between a first load electrode and a second load electrode, at least one gate driver, each of the at least one gate driver being configured to generate one or more control signals for one or more of the first and second controllable semiconductor device, and a plurality of lead frames, wherein the first controllable semiconductor device is arranged on and electrically coupled to a first lead frame of the plurality of lead frames, and the second controllable semiconductor device is arranged on and electrically coupled to a second lead frame of the plurality of lead frames, the first controllable semiconductor device, the second controllable semiconductor device, and the at least one gate driver are arranged in a molded package, and each of the plurality of lead frames is partly covered by the molded package and has at least one surface or section that is not covered by the molded package.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional side-view of a semiconductor arrangement.

FIG. 2 is a cross-sectional side-view of a semiconductor element of a semiconductor module arrangement according to embodiments of the disclosure.

FIG. 3 is a cross sectional side-view of a semiconductor arrangement according to embodiments of the disclosure.

FIG. 4 schematically illustrates a top view of a semiconductor module arrangement according to embodiments of the disclosure.

FIG. 5 is a cross sectional side-view of a semiconductor arrangement according to further embodiments of the disclosure.

FIG. 6 schematically illustrates a top view of a semiconductor module arrangement according to further embodiments of the disclosure.

FIG. 7 schematically illustrates a top view of a semiconductor module arrangement according to even further embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable).

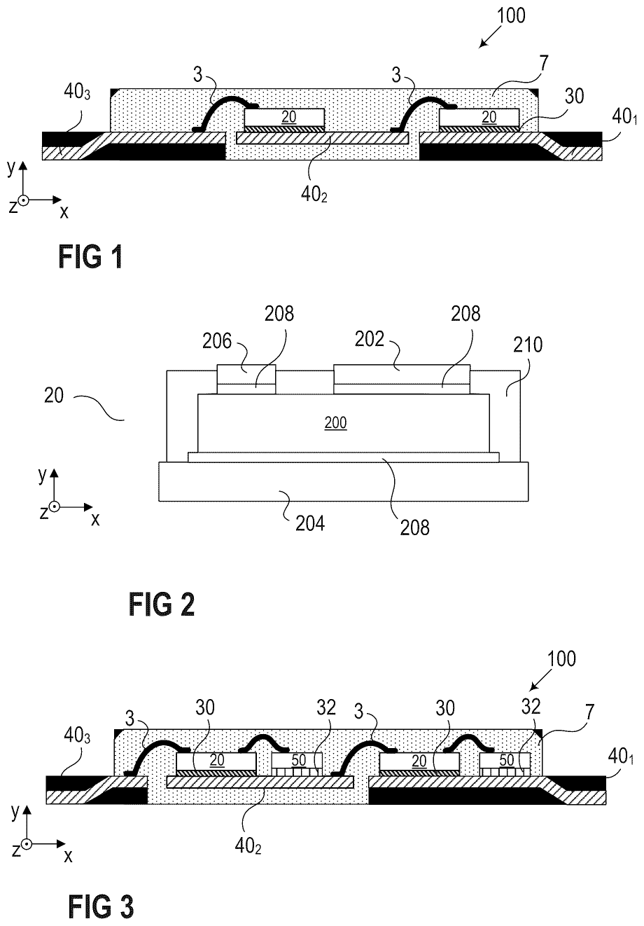

Referring to FIG. 1, a cross-sectional side-view of a semiconductor arrangement 100 is schematically illustrated. The semiconductor arrangement 100 comprises a plurality of controllable semiconductor devices 20, and a plurality of lead frames 40. Each controllable semiconductor device 20 of the plurality of controllable semiconductor devices 20 is arranged on one of the plurality of lead frames 40. Each controllable semiconductor device 20 of the plurality of controllable semiconductor devices 20 may be or may comprise a power switching device such as, e.g., an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable semiconductor element. The controllable semiconductor devices 20 may form a semiconductor arrangement such as, e.g., a half-bridge arrangement. In FIG. 1, two controllable semiconductor devices 20 are exemplarily illustrated. A semiconductor arrangement 100, however, may generally comprise any number of controllable semiconductor devices 20. That is, a semiconductor arrangement 100 may also comprise more than two controllable semiconductor devices 20. The semiconductor arrangement 100 in this example includes three different lead frames. Different controllable semiconductor devices 20 may be mounted on the same or on different lead frames 40. Different lead frames 40 may have no electrical connection or may be electrically connected to one or more other lead frames 40 (e.g., directly or via one of the plurality of controllable semiconductor devices 20) using electrical connections 3, e.g., bonding wires, or bonding ribbons. Each controllable semiconductor device 20 of the one or more controllable semiconductor devices 20 may be electrically and mechanically connected to a lead frame 40 by means of an electrically conductive connection layer 30. Such an electrically conductive connection layer 30 may be a solder layer, a layer of an electrically conductive adhesive, or a layer of a sintered metal powder, e.g., a sintered silver powder, for example.

The plurality of controllable semiconductor devices 20 are arranged in a molded package 7. Electrical connections between the controllable semiconductor devices 20 and an outside of the package 7 are provided by means of the plurality of lead frames 40. Each lead frame 40 generally provides a flat mounting area arranged inside the housing 7. None, one or more controllable semiconductor devices 20 may be arranged on different ones of the plurality of flat mounting areas inside the package. An end of a lead frame 40 opposite the flat mounting area and extending to the outside of the package 7 may be angled with respect to the flat mounting area, as is exemplarily illustrated in FIG. 1. In this way, it may be easier to contact the ends of the lead frames 40. In the semiconductor arrangement 100 illustrated in FIG. 1, each flat mounting area of the plurality of flat mounting areas provided by the lead frames 40 inside the package 7 are arranged in the same plane. This, however, is only an example. As will be described below, different ones of the flat mounting areas may also be arranged in different planes. Different lead frames 40 of a semiconductor arrangement 100 may be coupled to the same electrical potential, or to different electrical potentials.

The controllable semiconductor devices 20 arranged on the lead frames 40 may be semiconductor chips that are not separately packaged in any way. That is, they may be so-called bare dies. Bare-die semiconductor chips, however, generally have to be handled carefully to avoid any damages thereto which might decrease the overall lifetime of the semiconductor module. Therefore, a semiconductor arrangement 100 may comprise at least one pre-packaged semiconductor chip. An exemplary pre-packaged semiconductor chip is schematically illustrated in FIG. 2 and will be described in further detail below.

Referring to FIG. 2, a controllable semiconductor device 20 may comprise a semiconductor chip 200 having a first, a second, and a third electrode. This semiconductor chip 200 corresponds to the semiconductor chips/bodies as used in conventional semiconductor module arrangements (bare die semiconductor chip). The controllable semiconductor device 20 as illustrated in FIG. 2, however, further comprises a first metallic layer 202 attached to a first electrode of the semiconductor chip 200 by means of an electrically conducting connection layer 208, a second metallic layer 204 attached to a second electrode of the semiconductor chip 200 by means of an electrically conducting connection layer 208, a third metallic layer 206 attached to a third electrode of the semiconductor chip 200 by means of an electrically conducting layer 208, and a dielectrically insulating layer 210 covering surfaces of the semiconductor chip 200, wherein surfaces of the first, second, and third metallic layers 202, 204, 206 that face away from the semiconductor chip 200 are not covered by the dielectrically insulating layer 210. The electrically conducting connection layers 208 may be solder layers, for example. That is, the first, second, and third metallic layers 202, 204, 206 allow to electrically contact the first, second, and third electrode of the semiconductor chip 200, respectively, that are arranged in the package formed by the dielectrically insulating layer 210.

The first electrode of the semiconductor chip 200 may be arranged on a first side of the semiconductor chip 200, and the second electrode of the semiconductor chip 200 may be arranged on a second side of the semiconductor chip 200 opposite the first side. The third electrode may be arranged on the same side as the first electrode, i.e. on the first side of the semiconductor chip 200. The first electrode may be a source or emitter electrode, the second electrode may be a drain or collector electrode, and the third electrode may be a gate or base electrode, for example.

Now referring to FIG. 3, a cross sectional side-view of a semiconductor arrangement 100 according to embodiments of the disclosure is schematically illustrated. The semiconductor arrangement 100 comprises a first controllable semiconductor device 20₁, and a second controllable semiconductor device 20₂ forming a half-bridge arrangement, each of the first and second controllable semiconductor device 20₁, 20₂ comprising a control electrode 206 and a controllable load path between a first load electrode 202 and a second load electrode 204. The semiconductor arrangement 100 further comprises at least one gate driver 50, each of the at least one gate driver 50 being configured to generate one or more control signals for one or more of the first and second controllable semiconductor device 20₁, 20₂. The semiconductor arrangement 100 further comprises a plurality of lead frames 40. The first controllable semiconductor device 20₁ is arranged on and electrically coupled to a first lead frame 40₁ of the plurality of lead frames 40, and the second controllable semiconductor device 20₂ is arranged on and electrically coupled to a second lead frame 40₂ of the plurality of lead frames 40. The first controllable semiconductor device 20₁, the second controllable semiconductor device 20₂, and the at least one gate driver 50 are arranged in a molded package 7, and each of the plurality of lead frames 40 is partly covered by the molded package 7 and has at least one surface or section that is not covered by the molded package 7.

Semiconductor arrangements 100 according to embodiments of the disclosure are small in size, have an optimized performance, and are capable also for high current ratings. The overall costs of a semiconductor arrangement 100 according to embodiments of the disclosure are significantly less as compared to, e.g., semiconductor arrangements as exemplarily illustrated in FIG. 1 which have to be suitably coupled to external gate drivers.

In the example illustrated in FIG. 3, two gate drivers 50 are exemplarily illustrated inside the molded package 7. This, however, is only an example. It may also suffice to only include one gate driver 50 in the semiconductor arrangement 100, as will be described in further detail below. Other semiconductor arrangements 100 may comprise even more than two gate drivers 50. This may be the case if the semiconductor arrangement 100 comprises more than just the first controllable semiconductor device 20₁ and the second controllable semiconductor device 20₂.

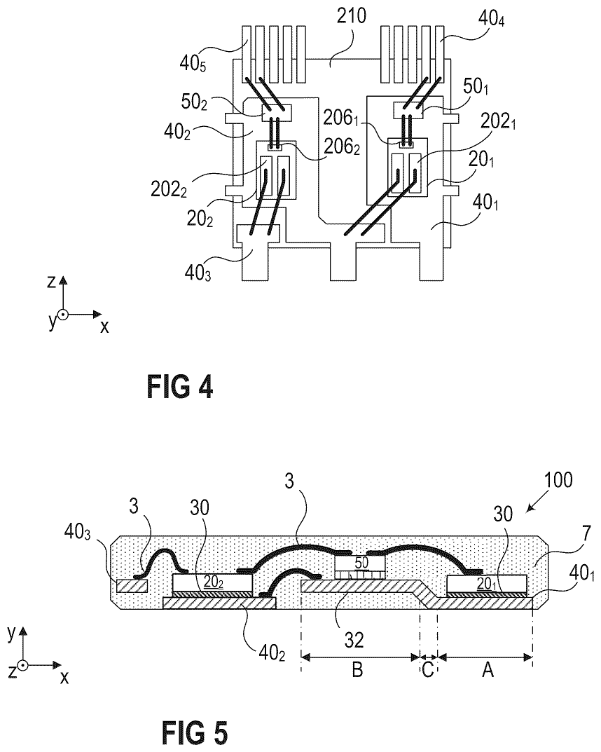

In a semiconductor arrangement 100 according to some embodiments of the disclosure, the first load electrode 202₁ of the first controllable semiconductor device 20₁ may be arranged on a first side of the first controllable semiconductor device 20₁ facing away from the first lead frame 40₁, the second load electrode 204₁ of the first controllable semiconductor device 20₁ may be arranged on a second side of the first controllable semiconductor device 20₁ opposite the first side and facing towards the first lead frame 40₁, and the control electrode 206₁ of the first controllable semiconductor device 20₁ may be arranged on the first side. Similarly, the first load electrode 202₂ of the second controllable semiconductor device 20₂ may be arranged on a first side of the second controllable semiconductor device 20₂ facing away from the second lead frame 40₂, the second load electrode 204₂ of the second controllable semiconductor device 20₂ may be arranged on a second side of the second controllable semiconductor device 20₂ opposite the first side and facing towards the second lead frame 40₂, and the control electrode 206₂ of the second controllable semiconductor device 20₂ may be arranged on the first side. This is schematically illustrated, for example, in the top view of FIG. 4, which exemplarily illustrates a semiconductor module arrangement according to embodiments of the disclosure.

The second load electrode 204 of each of the first and second controllable semiconductor device 20₁, 20₂ may be attached and electrically coupled to the respective lead frame 40₁, 40₂ by means of an electrically conductive connection layer 30, for example. Each of the at least one electrically conductive connection layer 30 may be a solder layer, a diffusion solder layer, a layer of an electrically conductive adhesive, or a layer of a sintered metal powder, for example.

In the example illustrated in FIG. 4, in order to form a half-bridge arrangement, the first load electrode 202₁ of the first controllable semiconductor device 20₁ is electrically coupled to the second lead frame 40₂ by means of one or more electrical connections 3. The first load electrode 202₂ of the second controllable semiconductor device 20₂ is electrically coupled to a third lead frame 40₃ by means of one or more electrical connections 3. The first lead frame 40₁ may be coupled to a first electrical potential (e.g., positive potential), and the third lead frame 40₃ may be coupled to a second electrical potential (e.g., negative potential) that is different from the first electrical potential. The second lead frame 40₂ may form or may be coupled to an output node which may be coupled to a load, for example.

Still referring to FIG. 4, a first gate driver 50₁ may be arranged on the first lead frame 40₁, and a second gate driver 50₂ may be arranged on the second lead frame 40₂. The first gate driver 50₁ in this example is configured to generate control signals for the first controllable semiconductor device 20₁, and the second gate driver 50₂ is configured to generate control signals for the second controllable semiconductor device 20₂. That is, the first gate driver 50₁ is electrically coupled to the control electrode 206₁ of the first controllable semiconductor device 20₁ by means of one or more electrical connections 3, and the second gate driver 50₂ is electrically coupled to the control electrode 206₂ of the second controllable semiconductor device 20₁ by means of one or more electrical connections 3. The first gate driver 50₁ in the example illustrated in FIG. 4 is electrically coupled to at least one fourth lead frame 40₄ by means of one or more electrical connections 3, each of the at least one fourth lead frame 40₄ comprising a first end arranged inside the molded package 7 and a second end extending to the outside of the molded package 7. The second gate driver 50₂ is electrically coupled to at least one fifth lead frame 40₅ by means of one or more electrical connections 3, each of the at least one fifth lead frame 40₅ comprising a first end arranged inside the molded package 7 and a second end extending to the outside of the molded package 7. The molded package 7 is not specifically illustrated in FIG. 4, as it would obstruct the view on the lead frames 40 and the controllable semiconductor devices 20 and gate drivers 50 arranged thereon.

In the example illustrated in FIG. 4, the flat mounting areas of the different lead frames 40 inside the package 7 are arranged in the same plane. This, however, is only an example. Referring to FIGS. 5, 6 and 7, for example, it is also possible that different ones of the flat mounting areas provided by the plurality of lead frames 40 are arranged in different planes. In these examples, the first lead frame 40₁ comprises a first section A extending in a first plane, a second section B extending in a second plane that is parallel to and distant from the first plane, and a third section C extending between the first section A and the second section B. The first controllable semiconductor device 20₁ in this example is arranged on a first surface of the first section A. The first surface of the first section A and the first controllable semiconductor device 20₁ arranged thereon are arranged in the molded package 7, and a second surface of the first section A opposite the first surface faces towards an outside of the molded package 7 (see, e.g., FIG. 5). The second lead frame 40₂ essentially extends in the first plane, and the second controllable semiconductor device 20₂ is arranged on a first surface of the second lead frame 40₂. The first surface of the second lead frame 40₂ and the second controllable semiconductor device 20₂ arranged thereon are arranged in the molded package 7, and a second surface of the second lead frame 40₂ opposite the first surface faces towards an outside of the molded package 7. The second section B of the first lead frame 40₁ is enclosed by the molded package 7. The second section B of the first lead frame 40₁ may be electrically contacted from the outside of the housing 7 via the first section A and the third section C.

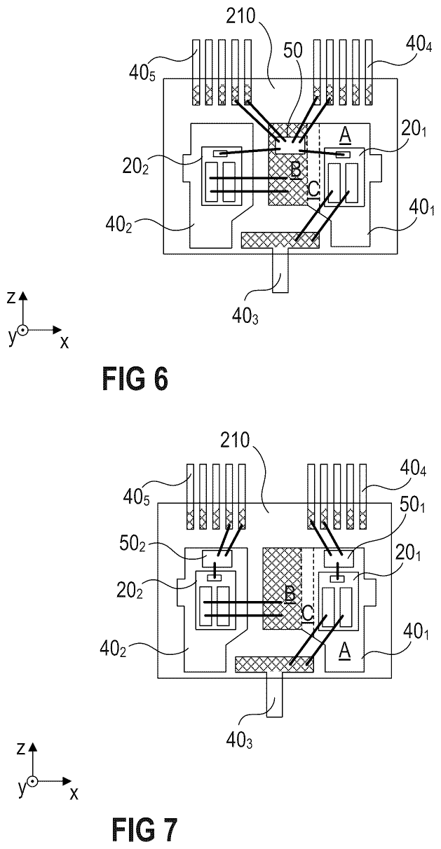

In the examples illustrated in FIGS. 5, 6 and 7, the first load electrode 202₂ of the second controllable semiconductor element 20₂ is electrically coupled to the first lead frame 40₁ by means of a first plurality of electrical connections 3, and the first load electrode 202₁ of the first controllable semiconductor element 20₁ is electrically coupled to a third lead frame 40₃ by means of a second plurality of electrical connections 3. Sections of the different lead frames 40 that are arranged in the second plane are illustrated crosshatched in FIGS. 6 and 7. As is schematically illustrated in FIGS. 5, 6 and 7, the second section B of the first lead frame 40₁ may be arranged closer to the second lead frame 40₂ than the first section A of the first lead frame 40₁.

According to some embodiments of the disclosure, the semiconductor arrangement 100 may comprise exactly one (not more than one) gate driver 50. This gate driver 50 may be arranged either on the first lead frame 40₁ or on the second lead frame 40₂, and is configured to generate first control signals for the first controllable semiconductor device 20₁ and second control signals for the second controllable semiconductor device 20₂. That is, this single gate driver 50 is electrically coupled to the control electrode 206₁ of the first controllable semiconductor element 20₁, as well as to the control electrode 206₂ of the second controllable semiconductor element 20₂. The gate driver 50 may comprise at least two inputs and at least two outputs. Control (e.g., gate driving) signals for the first controllable semiconductor device 20₁ may be provided at at least one first output, and control (e.g., gate driving) signals for the second controllable semiconductor device 20₂ may be provided at at least one second output.

The gate driver 50 (e.g., at least one first input of the gate driver 50), as is exemplarily illustrated in FIG. 6, may be electrically coupled to at least one fourth lead frame 40₄, each of the at least one fourth lead frame 40₄ comprising a first end arranged inside the molded package 7 and a second end extending to the outside of the molded package 7. The gate driver 50 (e.g., at least one second input of the gate driver 50) may be further electrically coupled to at least one fifth lead frame 40₅, each of the at least one fifth lead frame 40₅ comprising a first end arranged inside the molded package 7 and a second end extending to the outside of the molded package 7. The gate driver 50, via the at least one fourth lead frame 40₄ and the at least one fifth lead frame 40₅, may receive respective inputs from an external microcontroller, for example, according to which it generates the control (gate driving) signals for the first and second controllable semiconductor devices 20₁, 20₂.

The first controllable semiconductor device 20₁ and the second controllable semiconductor device 20₂ may be arranged on respective sections of the first and second lead frame 40₁, 40₂ that each extend in a first plane. In the example illustrated in FIG. 6, the gate driver 50 is arranged on a section B of the first lead frame 40₁ that extends in a second plane that is different from the first plane. In this way, the single gate driver 50 is arranged between the first and second controllable semiconductor devices 20₁, 20₂. Electrical connections 3 between the gate driver 50 and the first and second controllable semiconductor devices 20₁, 20₂, the first lead frame 40₁, and the second lead frame 40₂ are comparably short if the gate driver 50 is arranged on the second section B of the first lead frame 40₁.

A semiconductor arrangement comprising a single (exactly one/not more than one) gate driver 50, however, is only an example. Referring to FIG. 7, for example, a semiconductor arrangement alternatively may comprise a first gate driver 50₁ arranged on the first lead frame 40₁, and configured to generate control signals for the first controllable semiconductor device 20₁, and a second gate driver 50₂ arranged on the second lead frame 40₂, and configured to generate control signals for the second controllable semiconductor device 20₂. That is, a separate gate driver 50₁, 50₂ is provided for each of the controllable semiconductor devices 20₁, 20₂. The first controllable semiconductor device 20₁ and the second controllable semiconductor device 20₂ may be arranged on respective sections of the first and second lead frame 40₁, 40₂ that each extend in a first plane, similar to what has been described with respect to FIG. 6 above. The first gate driver 50₁ may be arranged on the same section of the first lead frame 40₁ and in the same plane as the first controllable semiconductor element 20₁, and the second gate driver 50₂ may be arranged on the second lead frame 40₂ and in the same plane as the second controllable semiconductor element 20₂.

In the example illustrated in FIG. 7, the first gate driver 50₁ is electrically coupled to at least one fourth lead frame 40₄, each of the at least one fourth lead frame 40₄ comprising a first end arranged inside the molded package 7 and a second end extending to the outside of the molded package 7. The second gate driver 50₂ is electrically coupled to at least one fifth lead frame 40₅, each of the at least one fifth lead frame 40₅ comprising a first end arranged inside the molded package 7 and a second end extending to the outside of the molded package 7. The first gate driver 50₁, via the at least one fourth lead frame 40₄, may receive respective inputs from an external microcontroller, for example, according to which it generates the control (gate driving) signals for the first controllable semiconductor device 20₁. The second gate driver 50₂, via the at least one fifth lead frame 40₅, may receive respective inputs from an external microcontroller, for example, according to which it generates the control (gate driving) signals for the second controllable semiconductor device 20₂.

In FIGS. 6 and 7, a total of five fourth lead frames 40₄, and a total of five fifth lead frames 40₅ is schematically illustrated. This, however, is only an example. A semiconductor arrangement may comprise less than five or even more than five fourth and fifth lead frames 40₄, 40₅. The number of fourth lead frames 40₄ and the number of fifth lead frames 40₅ also does not necessarily have to be identical. The gate driver 50 as illustrated in FIG. 6 is electrically coupled to only a subset (i.e. two) of the fourth lead frames 40₄ and to only a subset (i.e. two) of the fifth lead frames 40₅. This is only an example. The gate driver 50 generally may be electrically coupled to only a subset (at least one but not all) or to all of the fourth and fifth lead frames 40₄, 40₅. This similarly applies for the first and second gate drivers 50₄, 50₅ as illustrated in FIG. 7.

Semiconductor arrangements 100 according to the various embodiments disclosed herein are small in size, have an optimized performance, and are capable also for high current ratings. The overall costs of a semiconductor arrangement 100 according to embodiments of the disclosure are significantly less as compared to conventional semiconductor arrangements without any gate drivers integrated therein.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor arrangement, comprising:
a first controllable semiconductor device and a second controllable semiconductor device forming a half-bridge arrangement, each of the first and the second controllable semiconductor device comprising a control electrode and a controllable load path between a first load electrode and a second load electrode;
at least one gate driver configured to generate one or more control signals for one or more of the first and the second controllable semiconductor device; and
a plurality of lead frames,
wherein the first controllable semiconductor device is arranged on and electrically coupled to a first lead frame of the plurality of lead frames,
wherein the second controllable semiconductor device is arranged on and electrically coupled to a second lead frame of the plurality of lead frames,
wherein the first controllable semiconductor device, the second controllable semiconductor device, and the at least one gate driver are arranged in a molded package, and
wherein each of the lead frames is partly covered by the molded package and has at least one surface or section that is not covered by the molded package.

2. The semiconductor arrangement of claim 1, wherein:
the first load electrode of the first controllable semiconductor device is arranged on a first side of the first controllable semiconductor device facing away from the first lead frame, the second load electrode of the first controllable semiconductor device is arranged on a second side of the first controllable semiconductor device opposite the first side and facing towards the first lead frame, and the control electrode of the first controllable semiconductor device is arranged on the first side; and
the first load electrode of the second controllable semiconductor device is arranged on a first side of the second controllable semiconductor device facing away from the second lead frame, the second load electrode of the second controllable semiconductor device is arranged on a second side of the second controllable semiconductor device opposite the first side and facing towards the second lead frame, and the control electrode of the second controllable semiconductor device is arranged on the first side.

3. The semiconductor arrangement of claim 1, wherein the second load electrode of each of the first and the second controllable semiconductor device is attached and electrically coupled to the respective lead frame by an electrically conductive connection layer.

4. The semiconductor arrangement of claim 3, wherein each of the at least one electrically conductive connection layer is a solder layer, a diffusion solder layer, a layer of an electrically conductive adhesive, or a layer of a sintered metal powder.

5. The semiconductor arrangement of claim 3, wherein:
the first load electrode of the second controllable semiconductor element is electrically coupled to the first lead frame by a first plurality of electrical connections; and
the first load electrode of the first controllable semiconductor element is electrically coupled to a third lead frame by a second plurality of electrical connections.

6. The semiconductor arrangement of claim 1, wherein:
the first lead frame comprises a first section extending in a first plane, a second section extending in a second plane that is parallel to and distant from the first plane, and a third section extending between the first section and the second section, the first controllable semiconductor device being arranged on a first surface of the first section, the first surface of the first section and the first controllable semiconductor device arranged thereon being arranged in the molded package, and a second surface of the first section opposite the first surface faces towards an outside of the molded package; and
the second lead frame essentially extends in the first plane, the second controllable semiconductor device is arranged on a first surface of the second lead frame, the first surface of the second lead frame and the second controllable semiconductor device arranged thereon being arranged in the molded package, and a second surface of the second lead frame opposite the first surface faces towards an outside of the molded package.

7. The semiconductor arrangement of claim 6, wherein the second section of the first lead frame is enclosed by the molded package.

8. The semiconductor arrangement of claim 6, wherein the second section of the first lead frame is arranged closer to the second lead frame than the first section of the first lead frame.

9. The semiconductor arrangement of claim 6, wherein the first plurality of electrical connections extends between the first load electrode of the second controllable semiconductor element and the second section of the first lead frame.

10. The semiconductor arrangement of claim 1, wherein the at least one gate driver comprises:
a first gate driver arranged on the first lead frame and configured to generate control signals for the first controllable semiconductor device; and
a second gate driver arranged on the second lead frame and configured to generate control signals for the second controllable semiconductor device.

11. The semiconductor arrangement of claim 10, wherein:
the first gate driver is arranged on a same section of the first lead frame and in a same plane as the first controllable semiconductor element; and
the second gate driver is arranged in a same plane as the second controllable semiconductor element.

12. The semiconductor arrangement of claim 10, wherein:
the first gate driver is electrically coupled to at least one fourth lead frame comprising a first end arranged inside the molded package and a second end extending to the outside of the molded package; and
the second gate driver is electrically coupled to at least one fifth lead frame comprising a first end arranged inside the molded package and a second end extending to the outside of the molded package.

13. The semiconductor arrangement of claim 1, wherein the at least one gate driver comprises exactly one gate driver arranged on the first lead frame or on the second lead frame, and configured to generate first control signals for the first controllable semiconductor device and second control signals for the second controllable semiconductor device.

14. The semiconductor arrangement of claim 13, wherein the first controllable semiconductor device and the second controllable semiconductor device are arranged on respective sections of the first and the second lead frame that each extend in a first plane, and the gate driver is arranged on a section of the first lead frame that extends in second plane that is different from the first plane.

15. The semiconductor arrangement of claim 13, wherein the gate driver is electrically coupled to at least one fourth lead frame comprising a first end arranged inside the molded package and a second end extending to the outside of the molded package, and wherein the gate driver is further electrically coupled to at least one fifth lead frame comprising a first end arranged inside the molded package and a second end extending to the outside of the molded package.

16. The semiconductor arrangement of claim 1, wherein each of the first and the second controllable semiconductor device comprises:
a semiconductor chip comprising a first, a second, and a third electrode;
a first metallic layer attached to the first electrode of the semiconductor chip by an electrically conducting connection layer, the first metallic layer forming the first load electrode;
a second metallic layer attached to the second electrode of the semiconductor chip by an electrically conducting connection layer, the second metallic layer forming the second load electrode;
a third metallic layer attached to the third electrode of the semiconductor chip by an electrically conducting connection layer, the third metallic layer forming the control electrode; and
a dielectrically insulating layer covering surfaces of the semiconductor chip, wherein surfaces of the first, the second, and the third metallic layer that face away from the semiconductor chip are not covered by the dielectrically insulating layer.
